(19) United States
(12) Patent Application Publication
(10) Pub. No.: US 2024/0242974 A1
(43) Pub. Date: Jul. 18, 2024

(54) DEVICES, SYSTEMS AND METHODS FOR REDUCING WARPAGE DURING FABRICATION OF DUAL SIDE MOLD MODULES

(71) Applicant: SKYWORKS SOLUTIONS, INC., Irvine, CA (US)

(72) Inventors: Howard E. CHEN, Anaheim, CA (US); Karen Guadalupe CAMARGO SOTO, San Luis Rio Colorado (MX); Heliodoro OSUNA ARAUJO, Mexicali (MX); Yi LIU, San Diego, CA (US)

(21) Appl. No.: 18/412,390

(22) Filed: Jan. 12, 2024

Related U.S. Application Data
(60) Provisional application No. 63/439,049, filed on Jan. 13, 2023.

(51) Int. Cl. H01L 21/56; H01L 21/48; H01L 21/67; H01L 23/552

(52) U.S. Cl. CPC H01L 21/561; H01L 21/4853; H01L 21/67121; H01L 21/67126; H01L 23/552

(57) ABSTRACT

Packaged modules can be manufactured by providing or forming a substrate panel having first and second sides, and an array of units, and mounting one or more devices on the first side of the substrate panel for each unit. A first mold layer can be formed over the first side of the substrate panel to provide an assembly, with the first mold layer having an initial thickness that is greater than a final thickness, such that the initial thickness is sufficiently large to prevent warpage of the assembly where a similar assembly having a first mold layer with the final thickness would warp. One or more process operations can be performed on the second side of the substrate panel of the assembly, and a thinning operation can reduce the thickness of the first mold layer from the initial thickness to the final thickness.

### CROSS-REFERENCE TO RELATED APPLICATION(S)

This application claims priority to U.S. Provisional Application No. 63/439,049 filed Jan. 13, 2023, entitled DEVICES, SYSTEMS AND METHODS FOR REDUCING WARPAGE DURING FABRICATION OF DUAL SIDE MOLD MODULES, the disclosure of which is hereby expressly incorporated by reference herein in its entirety.

### BACKGROUND

### Field

The present disclosure relates to devices, systems and methods related to fabrication of dual side mold radio-frequency (RF) modules.

### Description of the Related Art

In many electronics applications, radio-frequency (RF) circuits and/or circuit elements are implemented as parts of packaged modules. A packaged module typically includes a substrate configured to receive and support a plurality of components such as semiconductor die and/or circuit elements such as discrete passive components. In some applications, such a packaged module can include one or more of the foregoing devices mounted on each of both sides of the substrate.

### SUMMARY

In accordance with some implementations, the present disclosure relates to a method for manufacturing packaged modules. The method includes providing or forming a substrate panel having first and second sides, and an array of units. The method further includes mounting one or more devices on the first side of the substrate panel for each unit, and forming a first mold layer over the first side of the substrate panel to provide an assembly. The first mold layer has an initial thickness that is greater than a final thickness, with the initial thickness being sufficiently large to prevent warpage of the assembly where a similar assembly having a first mold layer with the final thickness would warp. The method further includes performing one or more process operations on the second side of the substrate panel of the assembly. The method further includes performing a thinning operation to reduce the thickness of the first mold layer from the initial thickness to the final thickness.

In some embodiments, the one or more operations performed on the second side of the substrate panel can include forming a plurality of conductive features and mounting a device. In some embodiments, the conductive features on the second side of the substrate panel can include an array of solder balls or an array of conductive posts.

In some embodiments, the one or more operations performed on the second side of the substrate panel can further include forming a second mold layer over the second side of the substrate panel. In some embodiments, the one or more operations performed on the second side of the substrate panel can further include performing a thinning operation to reduce the thickness of the second mold layer to a final value.

In some embodiments, the forming of the second mold layer can result in the second mold layer covering the device and the conductive features on the second side of the substrate panel. In some embodiments, the one or more operations performed on the second side of the substrate panel can further include performing a thinning operation to expose a surface of each of the conductive features.

In some embodiments, the forming of the first mold layer can include a molding operation that results in a mold thickness that is greater than the initial thickness, followed by a thinning operation to reduce the thickness of the first mold layer from the mold thickness value to the initial thickness. In some embodiments, the thinning operation can include a grinding operation on the first mold layer.

In some embodiments, the forming of the first mold layer can result in the first mold layer having the initial thickness without any thinning operation. The first mold layer can include a surface resulting from a molding operation.

In some embodiments, the performing of the one or more process operations on the second side of the substrate panel can be achieved after the forming of the first mold layer over the first side of the substrate panel. The performing of the thinning operation to reduce the thickness of the first mold layer from the initial thickness to the final thickness can be achieved after the performing of the one or more process operations on the second side of the substrate panel. The thinning operation can include a grinding operation on the first mold layer.

In some embodiments, the method can further include performing a singulating operation to provide a packaged module corresponding to each of the array of units. In some embodiments, the method can further include forming a shielding layer to substantially cover all exposed surfaces of a first mold structure of each packaged module, lateral side surfaces of a substrate of the packaged module, and lateral side surfaces of a second mold structure of the packaged module, with the first mold structure, substrate and second mold structure corresponding to the respective unit portion of the first module layer, substrate panel and second mold layer.

In some implementations, the present disclosure relates to a system for manufacturing packaged modules. The system includes a panel handling component configured to handle a substrate panel having first and second sides, and an array of units. The system further includes an assembly component configured to mount one or more devices on the first side of the substrate panel for each unit, and a molding component configured to form a first mold layer over the first side of the substrate panel to provide an assembly, such that the first mold layer has an initial thickness that is greater than a final thickness, with the initial thickness being sufficiently large to prevent warpage of the assembly where a similar assembly having a first mold layer with the final thickness would warp. The system further includes one or more components configured to perform one or more process operations on the second side of the substrate panel of the assembly. The system further includes a thinning component configured to perform a thinning operation to reduce the thickness of the first mold layer from the initial thickness to the final thickness.

In some embodiments, the system can further include a singulation component configured to perform a singulation operation to provide a packaged module for each of the array of units. In some embodiments, the system can further include a deposition component configured to form a shielding layer to substantially cover all exposed surfaces of a first mold structure of each packaged module, lateral side surfaces of a substrate of the packaged module, and lateral side surfaces of a second mold structure of the packaged module, with the first mold structure, substrate and second mold structure corresponding to the respective unit portion of the first module layer, substrate panel and second mold layer.

In some embodiments, the thinning component can include a grinding apparatus configured to perform a grinding operation on the first mold layer.

In some implementations, the present disclosure relates to an assembly that includes a substrate panel having first and second sides, and configured to provide an array of units. The assembly further includes one or more devices on the first side of the substrate panel for each unit, and a first mold layer over the first side of the substrate panel, with the first mold layer having a thickness sufficiently large to prevent warpage of the assembly where a similar assembly having a first mold layer with a final thickness would warp. The second side of the substrate panel is configured to allow implementation of a second side portion, with the second side portion including one or more devices and an array of conductive features for each unit, and a second mold layer.

In some embodiments, the first mold layer can have a surface resulting from a mold formation operation that provides the first mold layer.

In some embodiments, the first mold layer can have a surface resulting from a thinning operation that provides the thickness of the first mold layer. The surface of the first mold layer can be a ground surface.

In some embodiments, the assembly can further include some or all of the second side portion implemented on the second side of the substrate panel.

In some embodiments, all of the second side portion can be implemented on the second side of the substrate panel. In some embodiments, the second mold layer can have a surface resulting from a mold formation operation that provides the second mold layer. In some embodiments, the second mold layer can have a surface resulting from a thinning operation that provides a desired thickness of the second mold layer. In such a configuration, the surface of the second mold layer can be a ground surface.

In some embodiments, the surface of the second mold layer can be configured to allow positioning of the assembly on a work surface and performing of a thinning operation on the first mold layer from the thickness to the final thickness. In some embodiments, the thinning operation on the first mold layer can include a grinding operation.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a plan view of a substrate panel including an array of units 110.

FIG. 1B shows a side view of the panel of FIG. 1A.

FIG. 1C shows an enlarged view of FIG. 1B.

FIG. 2 shows an example of an individual packaged module that can result from a panel-format fabrication process.

FIGS. 3A to 3E show an example of how warpage can occur for a panel-format assembly.

FIG. 4A shows that in some embodiments, a mold layer of a panel-format assembly can be dimensioned to provide a selected thickness that is greater than a thickness of a first mold on the corresponding side of a resulting packaged module.

FIG. 4B shows the panel-format assembly of FIG. 4A positioned on a flat surface, such that the surface of the mold layer substantially engages the flat surface and the second side of the substrate panel is oriented to allow further processing of the panel-format assembly.

FIG. 4C shows an enlarged view of a portion indicated in FIG. 4B.

FIG. 4D also shows another enlarged view of the same portion indicated in FIG. 4B.

FIGS. 5A to 5K show an example of how packaged modules can be manufactured utilizing one or more features as described herein.

FIG. 5L shows that in some embodiments, a packaged module manufactured in accordance to FIGS. 5A to 5K can be further processed to provide an exterior shielding functionality.

FIG. 6 shows that in some embodiments, one or more features of the present disclosure can be implemented in a module packaging system.

### DETAILED DESCRIPTION OF SOME EMBODIMENTS

The headings provided herein, if any, are for convenience only and do not necessarily affect the scope or meaning of the claimed invention.

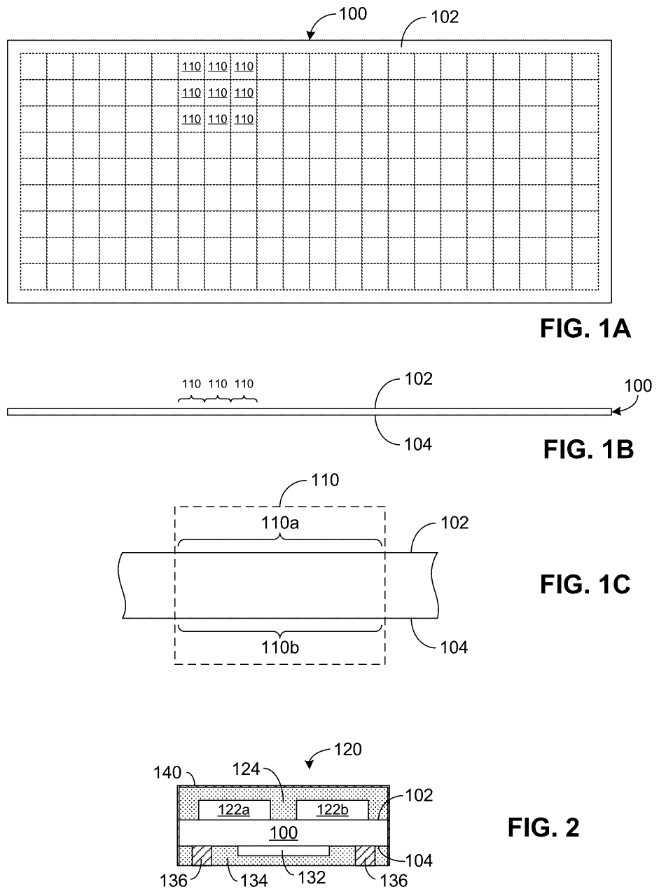

FIG. 1A shows a plan view of a substrate panel 100 including an array of units 110. FIG. 1B shows a side view of the panel 100 of FIG. 1A, and FIG. 1C shows an enlarged view of FIG. 1B. Referring to FIGS. 1A to 1C, the substrate panel 100 is shown to include a first side 102 and a second side 104. As depicted in FIG. 1C, each unit 110 can include a first side portion 110a on the first side 102 of the substrate panel 100 and a second side portion 110b on the second side 104 of the substrate panel 100.

In some module manufacturing processes, the substrate panel 100 of FIGS. 1A to 1C is utilized to process the first side 102, followed by processing of the second side 104. More particularly, and as an example, one or more devices (e.g., die and/or passive device(s)) can be provided on each first side portion 110a, and a first mold can be formed on the first side 102 to cover all of the first side portions 110a. Then, conductive features (e.g., ball-grid array or conductive posts) and one or more devices (e.g., die and/or passive device(s)) can be provided on each second side portion 110b, and a second mold can be formed on the second side 104 to cover all of the devices and provide exposed surfaces of the respective conductive features of the second side portions 110b.

Upon completion of the foregoing processing of both sides, the panel-format processed assembly can then be singulated to provide multiple individual packaged modules. FIG. 2 shows an example of an individual packaged module 120 that can result from the foregoing panel-format processing of both sides followed by singulation. In the example of FIG. 2, the packaged module 120 is shown to include a conformal shielding layer 140 implemented to cover a first side of the module 120 corresponding to the first side 102 of the substrate 100, as well as lateral sides of the module 120. However, it will be understood that packaged modules manufactured as described herein may or may not include such a shielding layer.

In the example of FIG. 2, devices 122a, 122b are shown to be mounted on the first side 102 of the substrate 100, and such devices are shown to be encapsulated by a first mold 124. On the second side 104 of the substrate 100, a device 132 is shown to be mounted thereto, and a plurality of conductive features 136 are shown to be provided to allow mounting of the packaged module 120 on a circuit board (not shown). Also on the second side 104 of the substrate 100, a second mold 134 is shown to be provided to encapsulate the device 132 and some or all of lateral sides of the conductive features 136.

In the example of FIG. 2, the first side 102 of the substrate 100 is shown to have two devices 122a, 122b mounted thereon. However, it will be understood that the first side 102 can have a different number of device(s) (e.g., one device or more than two devices) mounted thereon. Similarly, the second side 104 of the substrate 100 is shown to have one device 132 mounted thereon. However, it will be understood that the second side 104 can have a different number of devices (e.g., more-than-one devices) mounted thereon.

In the example of FIG. 2, the packaged module 120 is configured to be mounted onto a circuit board utilizing the exposed portions of the conductive features 136. Thus, if such a mounting of the packaged module 120 occurs on an upper surface of the circuit board, the mounting side of the packaged module 120 corresponding to the second mold 134 may be referred to as an underside, and the other side of the packaged module 120 corresponding to the first mold 124 may be referred to as an upper side. Accordingly, for the purpose of description, the first and second sides 102, 104 of the substrate 100 of FIG. 2, as well as the first and second sides 102, 104 of the substrate panel 100 of FIGS. 1A to 1C, may be referred to herein as upper side and underside, respectively. Further, a packaged module configured in the foregoing manner can be referred to as a dual-sided packaged module, a dual-sided module, a dual side module, a dual side package, etc.

Additional examples related to underside configurations of packaged modules, including examples of conductive features (136 in FIG. 2), are provided in U.S. Publication No. 2022/0319968 titled MODULE HAVING DUAL SIDE MOLD WITH METAL POSTS, and PCT Publication No. WO 2018/067578 titled DUAL-SIDED RADIO-FREQUENCY PACKAGE WITH OVERMOLD STRUCTURE, with each being expressly incorporated by reference in its entirely, and its disclosure is to be considered part of the specification of the present application.

For example, a packaged module having one or more features as described herein can include conductive features (136 in FIG. 2) having a ball shape or partial-ball shape.

In a more specific example, an array of solder balls can be provided on an underside of a substrate, and a mold structure can be provided on the underside of the substrate to partially or fully cover the solder balls. A thinning process can provide desired exposed surfaces of the solder balls to allow mounting of the resulting module onto a circuit board.

In another more specific example, a mold structure can be provided on an underside of a substrate, and an array of cavities can be formed on the mold structure. Then, solder balls can be provided within the cavities to provide through-mold connections. In such an example, the height of the solder balls can be lower than, approximately equal to, or higher than the height of the mold structure. In some embodiments, an additional conductive material may be provided over the exposed portion of each solder ball to provide desired electrical connectivity and/or thermal conductivity associated with the solder ball.

In another example, a packaged module having one or more features as described herein can include conductive features (136 in FIG. 2) implemented as conductive posts.

In a more specific example, a conductive post such as a copper post can be implemented on an underside of a substrate to provide an electrical connection for the packaged module. Such a conductive post can be formed from conductive material having a sufficiently high melting temperature so that the conductive post do not melt during a mounting operation such as a reflow soldering operation. In some embodiments, the conductive post can have a surface that is substantially coplanar with or recessed with respect to a mounting surface of the mold structure on the underside of the substrate. In some embodiments, the surface of the conductive post can be covered by a solderable material layer. In some embodiments, the solderable material layer can be implemented so that it protrudes beyond the mounting surface of the mold structure if the surface of the conductive post is substantially coplanar with the mounting surface of the mold structure. In some embodiments, the solderable material layer can be implemented so that it partially or fully fills the recess defined by the surface of the conductive post and the mounting surface of the mold structure.

It is noted that in some applications, it is desirable to have a reduced overall thickness for a dual side package. Such a reduction in the overall thickness can be achieved by use of a thinner substrate and/or thinner device(s) mounted on either or both sides of a substrate to allow use of corresponding thinner mold structure(s). However, manufacturing of such thinner dual side packages can encounter difficulty during a panel-format process.

For example, if a panel-format assembly including a substrate panel and a mold layer thereon is sufficiently thin, a difference in coefficients of thermal expansion (CTEs) of the substrate panel and the mold layer can result in significant warpage of the panel-format assembly. Such a warpage can occur upon formation of the mold layer on the respective side of the substrate panel, and/or during a subsequent process step when heat is applied to the panel-format assembly for further processing. Regardless, the warpage can result in further processing (e.g., with an automatic handling equipment) of the panel-format assembly to be impossible or impractical.

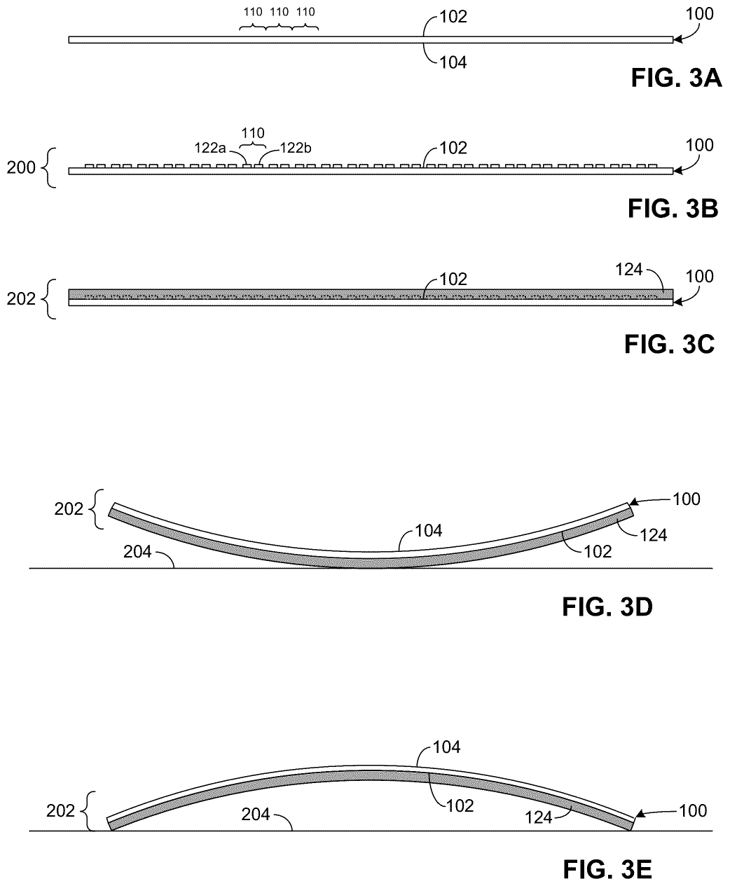

FIGS. 3A to 3E show an example of how warpage can occur for a panel-format assembly. FIG. 3A shows a side view of a substrate panel 100 having first and second sides 102, 104 and an array of units 110. In the example of FIG. 3A, the substrate panel 100 can have a relatively uniform coefficient of thermal expansion (CTE), such that warpage is not a problem even if made to be relatively thin.

FIG. 3B shows an assembly 200 resulting from mounting of example devices 122a, 122b on the first side 102 of each unit 110. In the example of FIG. 3B, the mounted devices (122a, 122b) may provide localized variations in CTE throughout the assembly 200; however, such localized CTE variations are shown to not impact the overall assembly 200 with warpage during one or more process steps associated with mounting of the devices 122a, 122b.

FIG. 3C shows an assembly 202 resulting from a mold layer 124 being formed on the first side 102 of the substrate panel 100 so as to encapsulate the devices (122a, 122b in FIG. 3B). In FIG. 3C, the assembly 202 is depicted as not warped; however, if the thickness of the mold layer 124 is sufficiently small and if the difference in CTEs of the mold layer 124 and the substrate panel 100 is sufficiently high, warpage can occur after the formation of the assembly 202 (e.g., during a cooling process) and/or during a subsequent process step (e.g., when heat is applied).

As described herein, the assembly 202 of FIG. 3C can warp. Examples of such a warpage are shown in FIGS. 3D and 3E, where the different warpages can depend on, for example, materials of the substrate panel 100 and the mold layer 124.

For example, FIG. 3D shows the assembly 202 of FIG. 3C in a warped configuration. In FIG. 3D, the warped assembly 202 is shown to be oriented and positioned on a surface 204 such that a portion of the mold layer 124 engages the surface 204 and the second side 104 of the substrate panel 100 faces upward in a concave manner for further processing of the assembly 202. However, the warpage is sufficiently severe such that subsequent process steps are either impossible or difficult.

In another example, FIG. 3E shows the assembly 202 of FIG. 3C in a warped configuration. In FIG. 3E, the warped assembly 202 is shown to be oriented and positioned on a surface 204 such that end portions of the mold layer 124 engage the surface 204 and the second side 104 of the substrate panel 100 faces upward in a convex manner for further processing of the assembly 202. However, the warpage is sufficiently severe such that subsequent process steps are either impossible or difficult.

In the examples of FIGS. 3D and 3E, the warpages as shown can depend on a number of factors including, for example, mechanical properties, CTEs and thicknesses of the substrate panel 100 and the mold layer 124, as well as one or more overall lateral dimensions of the assembly 202. It is noted that some substrate panels have one or more layers formed with dielectric material, and such dielectric layer(s) can provide a major factor that contributes to warpage. Thus, in some embodiments, one or more features of the present disclosure can be particularly beneficial when manufacturing packaged modules utilizing a substrate panel having one or more dielectric layers.

By way of an example, a 7-layer PCB-type substrate panel having lateral dimensions of 60 mm×186 mm to 95 mm×240 mm and a thickness of approximately 0.204 mm is provided with a mold layer formed by a transfer or compression mold process on the first side of the substrate panel so as to have a mold layer thickness of approximately 0.320 mm and lateral dimensions similar to those of the substrate panel. Configured as such, the resulting assembly can warp significantly during some or all of a mold step, a post-mold cure step, and any reflow steps.

In some implementations, the present disclosure relates to methods, assemblies and systems configured to support manufacturing of dual-sided packaged modules utilizing a panel-format, such that warpage of a panel-format assembly is substantially removed or within some acceptable range.

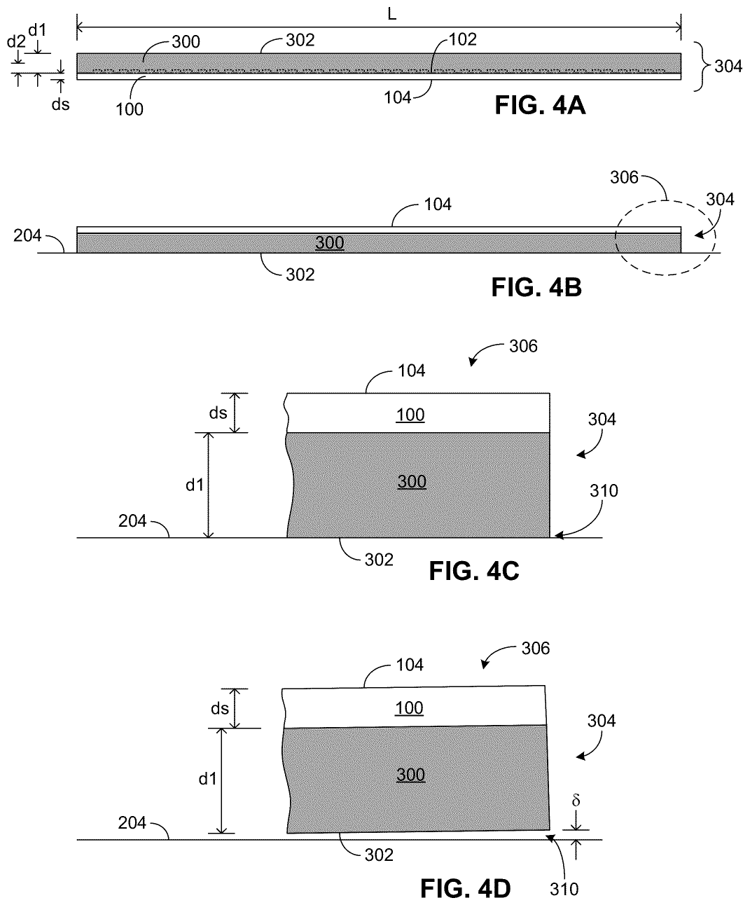

For example, FIG. 4A shows a side view of a panel-format assembly 304 that includes a substrate panel 100 having a thickness ds between first and second sides 102, 104. On the first side 102 of the substrate panel 100, one or more devices is/are mounted for each of an array of units (e.g., 110 in FIG. 1A). The panel-format assembly 304 is shown to further include a mold layer 300 provided on the first side 102 of the substrate panel 100 to encapsulate the devices mounted thereon and define a surface 302.

FIG. 4A shows that in some embodiments, the mold layer 300 of the panel-format assembly 304 can be dimensioned to provide a selected thickness d1 that is greater than a thickness d2 of a first mold (e.g., first mold 124 in FIG. 2) on the corresponding side of a resulting packaged module. In some embodiments, the thickness d1 can be selected to resist warpage of the assembly 304 based on, for example, one or more properties (e.g., material and/or dimensions) of the substrate panel 100 and one or more properties (e.g., material and/or dimensions) of the mold layer 300. Examples related to such a mold layer having a selected thickness d1 are described herein in greater detail.

FIG. 4B shows the panel-format assembly 304 of FIG. 4A positioned on a flat surface 204, such that the surface 302 of the mold layer 300 substantially engages the flat surface 204 and the second side 104 of the substrate panel 100 is oriented to allow further processing of the panel-format assembly 304. As described in reference to FIG. 4A, the selected thickness d1 of the mold layer 300 allows the panel-format assembly 304 to remain substantially planar or within some acceptable range to allow the further processing.

FIG. 4C shows an enlarged view of a portion indicated as 306 in FIG. 4B. FIG. 4D also shows an enlarged view of the same portion 306 in FIG. 4B. FIG. 4C shows an example where the panel-format assembly 304 remains substantially planar such that the surface 302 of the mold layer 300 engages the surface 204 at an interface 310 in a substantially co-planar manner. FIG. 4D shows an example where any deviation due to warpage is less than or equal to a maximum deviation δ at an interface 310, where the maximum deviation δ is within a range considered to be acceptable for further processing of the assembly 340.

In the example of FIG. 4D, the maximum deviation δ is depicted to occur at one lateral end of the assembly 304, in the example context of FIG. 3D where the warpage is shown to form a concave shape with respect to a location above the assembly 202. However, it will be understood that warpages may result in different shape where maximum deviations may or may not be at a lateral end. Thus, it will be understood that the maximum deviation δ of FIG. 4D is an example, and maximum deviation(s) can occur at one or more other locations of the assembly 340.

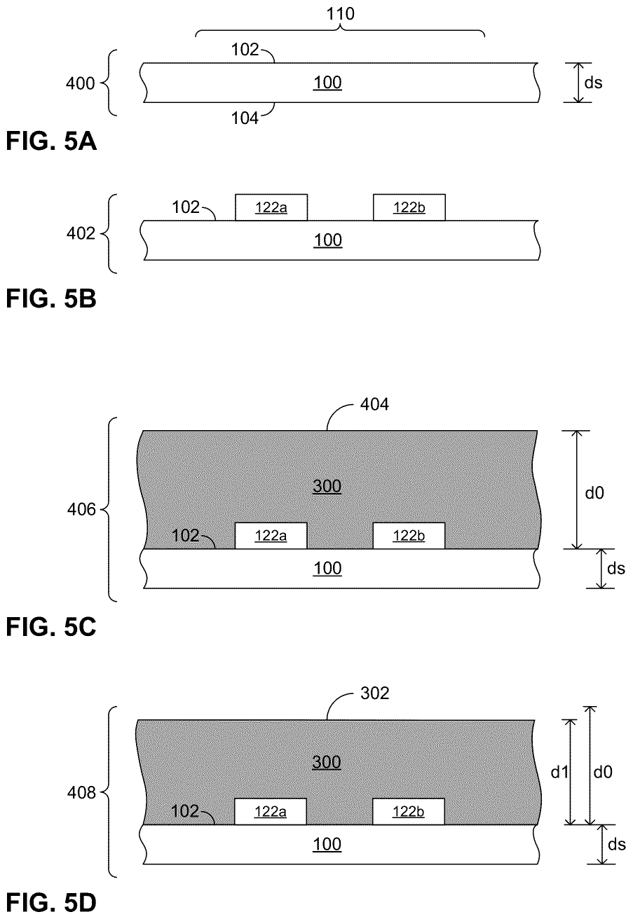

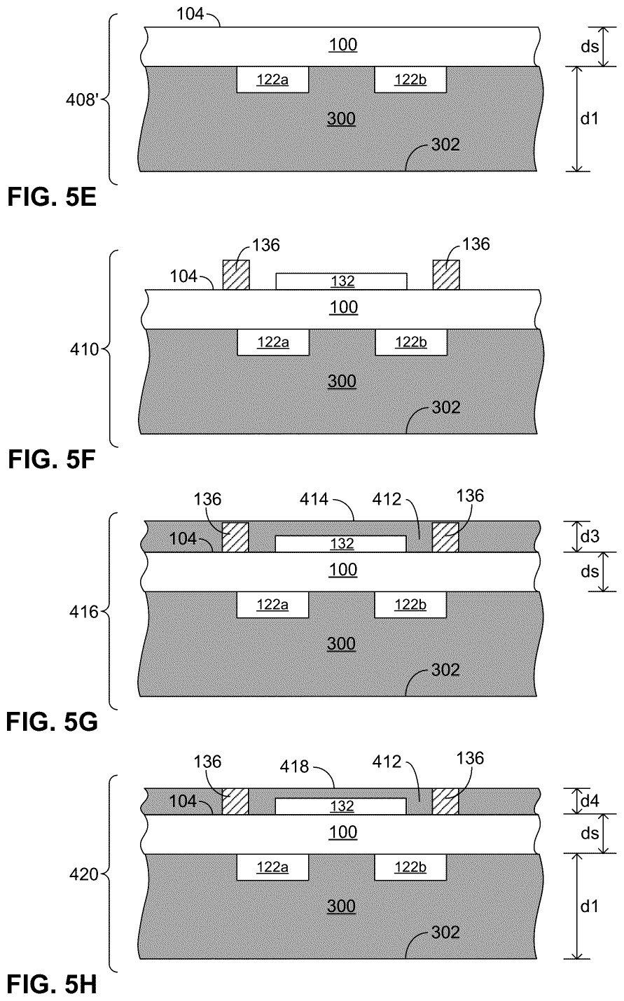

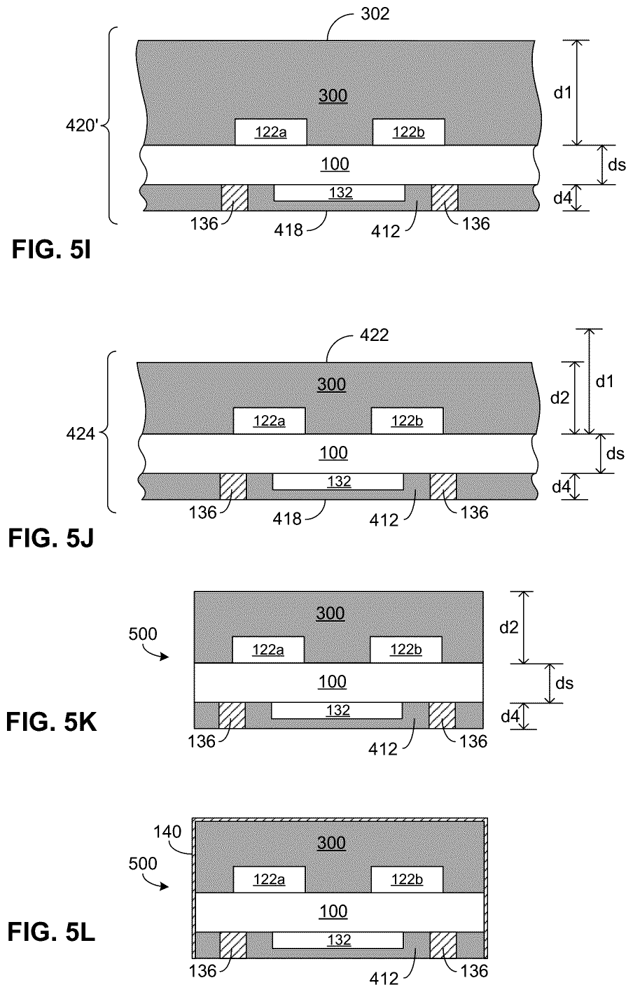

FIGS. 5A to 5K show an example of how packaged modules can be manufactured utilizing one or more features as described herein. In FIG. 5A, a substrate panel 100 can be provided or formed as an assembly 400. In some embodiments, such a substrate panel 100 can include multiple layers of substrate materials such as printed circuit board (PCB) material, to provide an overall thickness ds. As described herein, the substrate panel 100 can include first and second sides 102, 104, and an array of units 110 to allow processing of such units while in an array format.

In FIG. 5B, one or more devices (e.g., 122a, 122b) can be mounted on the first side 102 of the substrate panel 100 for each unit to form an assembly 402. In some embodiments, such devices can include, for example, one or more semiconductor die and/or one or more passive circuit elements.

In FIG. 5C, a relatively thick mold layer 300 can be formed over the first side 102 of the substrate panel 100 to encapsulate the devices 122a, 122b to yield an assembly 406. In FIG. 5C, the relatively thick mold layer 300 can have a thickness do and define a surface 404. In some embodiments, the thickness do can be greater than the selected thickness d1 of FIGS. 4A to 4D.

In FIG. 5D, the thick mold layer 300 can be thinned to provide a selected thickness d1 that is similar to the example of FIGS. 4A to 4D, to provide an assembly 408. In some embodiments, such a thinning process can include a grinding process to yield a surface 302. With such a thinning process, the resulting surface 302 and the selected thickness d1 can be controlled better than the surface 404 and thickness do resulting from the molding process of FIG. 5C.

FIG. 5E shows the assembly 408 of FIG. 5D in an inverted orientation (indicated as 408′). In such an orientation, the surface 302 of the mold layer 300 (now thinned to the selected thickness d1) can be placed on a work surface to allow further process steps to be performed on the second side 104 of the substrate panel 100.

FIGS. 5F to 5H show various stages of such process steps in an example context of conductive posts; and additional details concerning such conductive posts can be found in U.S. Publication No. 2022/0319968 referenced herein. It will be understood that in some embodiments, the process steps performed on the second side 104 of the substrate panel 100 can include other types of conductive features such as solder balls; and additional details concerning such solder balls can be found in PCT Publication No. WO 2018/067578 also referenced herein. It will also be understood that the process steps performed on the second side 104 of the substrate panel 100 can include conductive feature configurations other than the foregoing examples.

In FIG. 5F, a plurality of conductive posts 136 and a device 132 are shown to be implemented on the second side 104 of the substrate panel 100 so as to yield an assembly 410.

In FIG. 5G, a mold layer 412 is shown to be formed over the second side 104 of the substrate panel 100 to provide a surface 414 and encapsulate the device 132 of each unit. In some embodiments, the mold layer 412 can also encapsulate some or all of the conductive posts 136 such that ends of the conductive posts may or may not be covered by the mold layer 412. In FIG. 5G, the mold layer 412 is shown to have a thickness of d3.

In FIG. 5H, the mold layer 412 can be thinned to provide a new thickness of d4 and a new surface 418 utilizing, for example, a grinding process, so as to yield an assembly 420. As described herein, such a grinding process can provide better thickness and surface control than the molding process. In FIG. 5H, the thinning process is shown to expose the ends of the conductive posts 136 to allow mounting of the resulting packaged module after singulation.

FIG. 5I shows the assembly 420 of FIG. 5H in an inverted orientation (with respect to the orientation of FIG. 5H, and indicated as 420′). In such an orientation, the surface 418 of the mold layer 412 can be placed on a work surface to allow further thinning of the mold layer 300 on the first side of the substrate panel 100.

It is noted that since the mold layer 412 is now present on the second side (104 in FIGS. 5G and 5H) of the substrate panel 100, further thinning of the mold layer 300 on the first side of the substrate panel 100 does not result in warpage, even if the thickness of the mold layer 300 is reduced to a thickness (e.g., d2 in FIG. 4A) that would have resulted in warpage without the presence of the second mold layer 412.

In FIG. 5J, the first mold layer 300 can be thinned to provide a new thickness of d2 and a new surface 422 utilizing, for example, a grinding process, so as to yield an assembly 424. As described herein, such a grinding process can provide better thickness and surface control than the molding process. In FIG. 5J, the thickness dimension d2 of the first mold layer 300 can be the final thickness of the first mold structure of the resulting packaged module. Similarly, the thickness dimension d4 of the second mold layer 412 can be the final thickness of the second mold structure of the resulting packaged module.

In FIG. 5K, the assembly 424 of FIG. 5J can be singulated to provide multiple packaged modules 500. Such a module is shown to have a configuration where both sides of the substrate 100 are provided with devices (e.g., 122a, 122b on the first side, and 132 on the second side) and respective mold structures (300 on the first side and 412 on the second side). In some embodiments, the packaged module 500 of FIG. 500 can be a completed packaged module without a shielding layer.

FIG. 5L shows that in some embodiments, the packaged module 500 of FIG. 5K can be further processed to provide an exterior shielding functionality. As described herein in reference to the example of FIG. 2, such a shielding functionality can be provided with a conformal shielding layer 140 implemented to cover the first side of the module 500 corresponding to the first side of the substrate 100, as well as lateral sides of the module 500.

Referring to FIGS. 5A to 5L, it is noted that three mold layer-thinning process steps are involved during the panel-format processing phase. Assuming that each thinning process includes a grinding process, and referring to FIGS. 5C and 5D, a first grinding process is utilized to reduce the thickness of the first mold layer 300 from a relatively thick dimension (d0) to a selected thickness (d1) that allows the resulting assembly to resist warping during one or more subsequent process steps. Referring to FIGS. 5G and 5H, a second grinding process is utilized to reduce the thickness (d3) of the second mold layer 412 to provide a desired thickness (d4) of the second mold layer 412 and expose the ends of the conductive features. Referring to FIGS. 51 and 5J, a third grinding process is utilized to reduce the thickness of the first mold layer 300 from the selected thickness (d1) utilized to process the second side of the substrate panel to a final thickness (d2). It is noted that without the selected thickness d1 being utilized during the processing of the second side of the substrate panel, warpage would occur if such processing of the second side is attempted with the final thickness d2 of the first mold layer 300.

In some embodiments, the various mold layer thickness values (e.g., d0, d1, d2, d3, d4) can be based on, for example, desired final thicknesses d2, d4 of the first and second mold layers, desired warpage resistance without unnecessarily thickness values, and desired efficiency in thinning processes. With respect to the second example above, it is noted that an unnecessarily large value of d1 will resist warpage; however, such a thick intermediate mold layer will need to be thinned to a much smaller thickness value, thereby resulting in an inefficient manufacturing process.

It is also noted that the selected thickness d1 of the first mold layer can depend of factors such as mechanical properties, CTEs and thicknesses of the substrate panel and the first mold layer, as well as one or more overall lateral dimensions of the corresponding assembly. Thus, for a given assembly of a substrate panel and a first mold layer, some threshold thickness value (d_{threshold}) can be determined (e.g., empirically), where a selected thickness d1 being less than d_{threshold} (d1<d_{threshold}) will likely result in warpage, and a configuration of d1>d_{threshold} will likely result in no warpage or acceptable amount of warpage.

Thus, in some embodiments, various thicknesses of the first mold layer can be determined as follows. The desired final thickness d2 of the first mold layer can be given based on specified dimensions of the corresponding packaged modules to be produced. The threshold thickness value d_{threshold} which is assumed to be greater than d2 can be determined empirically, by simulations, or some combinations thereof, based on some or all of the example factors discussed above. Then, a selected thickness d1 can be implemented to be α×d2, where the multiplier α is in a range of, for example, 1.10 to 2.00, 1.15 to 1.75, or 1.20 to 1.50. Then, a first thickness d0 of the first mold layer can be implemented to be β×d1, where the multiplier β is in a range of, for example, 1.02 to 1.50, 1.03 to 1.30, or 1.05 to 1.20.

By way of an example, multiple packaged modules were manufactured without significant panel-warpage utilizing one or more features of the present disclosure. In the example, the modules' design specified the substrate thickness to be ds=0.204 mm, and the first mold layer thickness to be d2=0.320 mm. Based on such parameters, first thickness of the first mold layer being d0=0.440 mm, and selected thickness of d1=0.400 mm, were utilized for processing of the second side of the corresponding panel assembly without warpage.

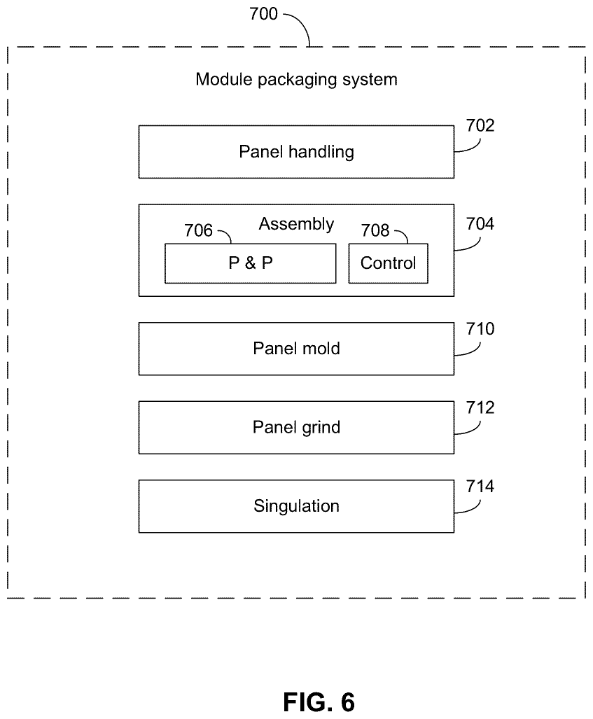

FIG. 6 shows that in some embodiments, one or more features of the present disclosure can be implemented in a module packaging system 700. Such a system can include a number of systems, subsystems, apparatus, etc. configured to provide respective functionalities. For example, a panel handling component 702 can be provided to allow handling of panel substrate panels and/or panel assemblies having mold layer(s) thereon.

In another example, an assembly component 704 can be provided to, for example, mounting of devices on either or both sides of substrate panels, and formation of conductive features on the second side of substrate panels. In some embodiments, such an assembly functionality can be supported by, for example, a pick-and-place apparatus 706 in operation with a controller 708.

In yet another example, a panel mold component 710 can be provided to form some or all of panel mold layers as described herein. In some embodiments, such panel mold layer forming component can be configured to form the initial panel mold layers on the first side of the substrate panels (to have a thickness of d0), as well as to form initial panel mold layers on the second side of the substrate panels (to have a thickness of d3).

In yet another example, a panel grind component 712 can be provided to perform thinning operations on either or both of the panel mold layers on the first and second sides of the substrate panels. In some embodiments, the three example grinding operations described herein in reference to FIGS. 5A to 5L can be performed by three separate dedicated grinding apparatus, a single grinding apparatus capable of providing varying thickness control, or some combination thereof.

In yet another example, a singulation component 714 can be provided to perform singulation operations on completed panel assemblies.

In some embodiments, some or all of the functional components of the module packaging system 700 of FIG. 6 can be performed under the control of, and/or facilitated by, a computer configured to execute one or more algorithms.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A method for manufacturing packaged modules, the method comprising:
providing or forming a substrate panel having first and second sides, and an array of units;
mounting one or more devices on the first side of the substrate panel for each unit;
forming a first mold layer over the first side of the substrate panel to provide an assembly, the first mold layer having an initial thickness that is greater than a final thickness, the initial thickness sufficiently large to prevent warpage of the assembly where a similar assembly having a first mold layer with the final thickness would warp;
performing one or more process operations on the second side of the substrate panel of the assembly; and
performing a thinning operation to reduce the thickness of the first mold layer from the initial thickness to the final thickness.

2. The method of claim 1 wherein the one or more operations performed on the second side of the substrate panel includes forming a plurality of conductive features and mounting a device.

3. The method of claim 2 wherein the conductive features on the second side of the substrate panel include an array of solder balls or an array of conductive posts.

4. The method of claim 2 wherein the one or more operations performed on the second side of the substrate panel further includes forming a second mold layer over the second side of the substrate panel.

5. The method of claim 4 wherein the one or more operations performed on the second side of the substrate panel further includes performing a thinning operation to reduce the thickness of the second mold layer to a final value.

6. The method of claim 4 wherein the forming of the second mold layer results in the second mold layer covering the device and the conductive features on the second side of the substrate panel.

7. The method of claim 6 wherein the one or more operations performed on the second side of the substrate panel further includes performing a thinning operation to expose a surface of each of the conductive features.

8. The method of claim 1 wherein the forming of the first mold layer includes a molding operation that results in a mold thickness that is greater than the initial thickness, followed by a thinning operation to reduce the thickness of the first mold layer from the mold thickness value to the initial thickness.

9. The method of claim 8 wherein the thinning operation includes a grinding operation on the first mold layer.

10. The method of claim 1 wherein the forming of the first mold layer results in the first mold layer having the initial thickness without any thinning operation.

11. The method of claim 10 wherein the first mold layer includes a surface resulting from a molding operation.

12. The method of claim 1 wherein the performing of the one or more process operations on the second side of the substrate panel is achieved after the forming of the first mold layer over the first side of the substrate panel.

13. The method of claim 12 wherein the performing of the thinning operation to reduce the thickness of the first mold layer from the initial thickness to the final thickness is achieved after the performing of the one or more process operations on the second side of the substrate panel.

14. The method of claim 13 wherein the thinning operation includes a grinding operation on the first mold layer.

15. The method of claim 1 further comprising performing a singulating operation to provide a packaged module corresponding to each of the array of units.

16. The method of claim 15 further comprising forming a shielding layer to substantially cover all exposed surfaces of a first mold structure of each packaged module, lateral side surfaces of a substrate of the packaged module, and lateral side surfaces of a second mold structure of the packaged module, the first mold structure, substrate and second mold structure corresponding to the respective unit portion of the first module layer, substrate panel and second mold layer.

17. A system for manufacturing packaged modules, the system comprising:
a panel handling component configured to handle a substrate panel having first and second sides, and an array of units;
an assembly component configured to mount one or more devices on the first side of the substrate panel for each unit;
a molding component configured to form a first mold layer over the first side of the substrate panel to provide an assembly, the first mold layer having an initial thickness that is greater than a final thickness, the initial thickness sufficiently large to prevent warpage of the assembly where a similar assembly having a first mold layer with the final thickness would warp;
one or more components configured to perform one or more process operations on the second side of the substrate panel of the assembly; and
a thinning component configured to perform a thinning operation to reduce the thickness of the first mold layer from the initial thickness to the final thickness.

18. The system of claim 17 further comprising a singulation component configured to perform a singulation operation to provide a packaged module for each of the array of units.

19. The system of claim 17 further comprising a deposition component configured to form a shielding layer to substantially cover all exposed surfaces of a first mold structure of each packaged module, lateral side surfaces of a substrate of the packaged module, and lateral side surfaces of a second mold structure of the packaged module, the first mold structure, substrate and second mold structure corresponding to the respective unit portion of the first module layer, substrate panel and second mold layer.

20. (canceled)

21. An assembly comprising:
a substrate panel having first and second sides, and configured to provide an array of units;
one or more devices on the first side of the substrate panel for each unit;
a first mold layer over the first side of the substrate panel, the first mold layer having a thickness sufficiently large to prevent warpage of the assembly where a similar assembly having a first mold layer with a final thickness would warp; and
the second side of the substrate panel configured to allow implementation of a second side portion, the second side portion including one or more devices and an array of conductive features for each unit, and a second mold layer.

22. (canceled)

23. (canceled)

24. (canceled)

25. (canceled)

26. (canceled)

27. (canceled)

28. (canceled)

29. (canceled)

30. (canceled)

31. (canceled)
